(19) United States
(12) Patent Application Publication
(10) Pub. No.: US 2025/0086368 A1
(43) Pub. Date: Mar. 13, 2025

(54) METHOD OF VERIFYING PROCESS DATA OF DISPLAY PANEL, METHOD OF MANUFACTURING DISPLAY PANEL AND ELECTRONIC DEVICE

(71) Applicants: BEIJING ZHONGXIANGYING TECHNOLOGY CO., LTD., Beijing (CN); BOE TECHNOLOGY GROUP CO., LTD., Beijing (CN)

(72) Inventors: Nan Liu, Beijing (CN); Xuemei Lin, Beijing (CN); Jianmin Wu, Beijing (CN); Hong Wang, Beijing (CN)

(21) Appl. No.: 18/552,435

(22) PCT Filed: Aug. 31, 2022
(86) PCT No.: PCT/CN2022/116149

§ 371 Date: Sep. 25, 2023

(51) Int. Cl. G06F 30/367

(52) U.S. Cl. CPC G06F 30/367

(57) ABSTRACT

Provided are a method of verifying process data of a display panel, a device, a storage medium, and a product, which relates to a field of process verification technology. The method of verifying the process data of the display panel includes: generating, based on design data of a process of the display panel, simulation process data for performing the process; performing, by using a process model, a simulation of performing the process based on the simulation process data; and verifying, by using a measurement model, whether the simulation process data is applicable to actual production based on the simulation. The process model is constructed based on actual process data generated in an actual manufacturing process of the display panel, and the measurement model is constructed based on actual process data and actual measurement data which are generated in the actual manufacturing process of the display panel.

### CROSS REFERENCE TO RELATED APPLICATION(S)

This application is a Section 371 National Stage Application of International Application No. PCT/CN2022/116149, filed on Aug. 31, 2022, entitled “METHOD OF VERIFYING PROCESS DATA OF DISPLAY PANEL, METHOD OF MANUFACTURING DISPLAY PANEL AND ELECTRONIC DEVICE”, which is incorporated herein in entirety by reference.

### TECHNICAL FIELD

The present disclosure relates to a field of process verification technology, and in particular to a method of verifying process data of a display panel, a method of manufacturing a display panel, an electronic device, a storage medium and a computer program product.

### BACKGROUND

Generally, display products require to be strictly standardly verified before being launched. For example, rationality verification is required for a manufacturing process stage, a vapor plating packaging process stage, and a module process stage of OLED products. Due to a process fluctuation of the device, multiple adjustments are required to achieve the process parameter(s) as desired by a design. This leads to a long time of a verification stage, especially the time required for the verification of new products will be longer, which affects a researching and developing of new products.

### SUMMARY

The present disclosure provides a method of verifying process data of a display panel, a method of manufacturing a display panel, an electronic device, a storage medium and a computer program product.

According to an aspect, the present disclosure provides a method of verifying process data of a display panel, including: generating, based on design data of a process of the display panel, simulation process data for performing the process; performing, by using a process model, a simulation of performing the process based on the simulation process data; and verifying, by using a measurement model, whether the simulation process data is applicable to actual production based on the simulation, wherein the process model is constructed based on actual process data generated in an actual manufacturing process of the display panel, and the measurement model is constructed based on actual process data and actual measurement data which are generated in the actual manufacturing process of the display panel.

For example, performing, by using a process model, a simulation of performing the process based on the simulation process data includes determining, by using the process model, feature data of the display panel achievable by performing the process based on the simulation process data.

For example, verifying, by using a measurement model, whether the simulation process data is applicable to actual production based on the simulation includes: determining, among the actual process data, the actual process data having a similarity higher than a preset similarity threshold with respect to the simulation process data, as similar process data by using the measurement model; determining, among the actual measurement data, feature data of the display panel obtained by actually performing the process based on the similar process data as actual feature data; and determining that the simulation process data is applicable to actual production, in response to a difference between the actual feature data and the feature data output by the process model being less than a preset difference threshold.

For example, the verification method further includes: before verifying, by using the measurement model, whether the simulation process data is applicable to actual production based on the simulation, calculating a process fluctuation by applying a feedback parameter algorithm to the actual process data by using a control model, and applying the process fluctuation to the feature data output by the process model.

For example, the feedback parameter algorithm includes one of a moving average algorithm, a weighted moving average algorithm, and an exponential moving average algorithm.

For example, the moving average algorithm includes calculating an average value of process parameters of a plurality of consecutive cycles according to an equation:

$$MA = \frac{{C}_{1} + {C}_{2} + ⋯ + {C}_{n}}{n}$$

where each C₁, C₂, . . . Cₙ is a value of the process parameter of a respective cycle, and n is an integer greater than 1.

For example, the weighted moving average algorithm includes one of a doomsday weighted algorithm, a linear weighted algorithm, a trapezoidal weighted algorithm, and a square coefficient weighted algorithm.

For example, the doomsday weighted algorithm includes calculating a weighted average value of process parameters of a plurality of consecutive cycles according to an equation:

$$WMA = \frac{{C}_{1} + {C}_{2} + ⋯ + {C}_{n} \times 2}{n + 1}$$

where each of C₁, C₂, . . . Cₙ is a value of the process parameter of a respective cycle, and n is an integer greater than 1.

For example, the linear weighted algorithm includes calculating a weighted average value of process parameters of a plurality of consecutive cycles according to an equation:

$$WMA = \frac{{C}_{1} \times 1 + {C}_{2} \times 2 + ⋯ + {C}_{n} \times n}{1 + 2 + 3 + ⋯ + n}$$

where each of C₁, C₂, . . . Cₙ is a value of the process parameter of a respective cycle, and n is an integer greater than 1.

For example, the trapezoidal weighted algorithm includes calculating a weighted average value of process parameters of a plurality of consecutive cycles according to an equation:

$$WMA = \frac{( {C}_{1} + {C}_{2} ) \times 1 + ( {C}_{2} + {C}_{3} ) \times 2 + ⋯ + ( {C}_{n - 1} + {C}_{n} ) \times ( n - 1 )}{2 \times 1 + 2 \times 2 + 2 \times 3 + ⋯ + 2 \times ( n - 1 )}$$

where each of C₁, C₂, . . . Cₙ is a value of the process parameter of a respective cycle, and n is an integer greater than 1.

For example, the square coefficient weighted algorithm includes calculating a weighted average value of process parameters of a plurality of consecutive cycles according to an equation:

$$WMA = \frac{{C}_{1} \times {1}^{2} + {C}_{2} \times {2}^{2} + ⋯ + {C}_{n} \times {n}^{2}}{{1}^{1} + {2}^{2} + {3}^{2} + ⋯ + {n}^{2}}$$

where each of C₁, C₂, . . . Cₙ is a value of the process parameter of a respective cycle, and n is an integer greater than 1.

For example, the exponential moving average algorithm includes calculating a weighted average value of process parameters of a plurality of consecutive cycles according to an equation:

$$EMA = \frac{{C}_{1} + ( 1 + α ) {C}_{2} + {( 1 + α )}^{2} {C}_{3} … + {( 1 + α )}^{n} {C}_{n}}{1 + ( 1 + α ) + {( 1 + α )}^{2} + ⋯ + {( 1 + α )}^{n}}$$

where each of C₁, C₂, . . . Cₙ is a value of the process parameter of a respective cycle, n is an integer greater than 1, and α is a weighted index.

For example, the process of the display panel includes a backplane manufacturing process.

For example, the process of the display panel includes a lithography process for forming a film layer in the backplane manufacturing process, the design data includes a design pattern of a mask, and the generating, based on design data of a process of the display panel, simulation process data for performing the process includes at least one of operations: simulating at least a part of the design pattern of the mask to obtain a test pattern; generating an exposure process parameter based on a received exposure parameter setting information; generating a resist process parameter based on a received resist parameter setting information; and generating a development process parameter based on a received development parameter setting information.

For example, generating the exposure process parameter includes at least one of a numerical aperture, a wavelength, a coherence factor, an illumination type, an exposure magnification, and a focus position.

For example, generating the resist process parameter includes at least one of a type of photoresist, a thickness and development rate of photoresist, a substrate material, and a concentration distribution of photosensitive compound (PAC).

For example, generating, based on design data of a process of the display panel, simulation process data for performing the process further includes at least one of following: performing lens projection simulation on the test pattern based on the exposure process parameter to obtain aerial image data; and generating graphic data of the film layer which has been developed, based on the development parameter.

For example, the verification method further includes: presenting at least one of the aerial image data and the graphic data through a user interaction interface and receiving an input from a user, and adjusting at least one of the exposure process parameter, the resist process parameter, and the development process parameter based on the input from the user.

For example, the actual measurement data includes data measured before starting the process and data measured after starting the process.

For example, the method further includes updating the actual process data and the actual measurement data; and updating the process model and the measurement model based on updated actual process data and updated actual measurement data.

For example, the method further includes applying the simulation process data to the actual manufacturing process of the display panel in response to verifying that the simulation process data is applicable to actual production.

For example, the verification method further includes forming the simulation process data which is verified to be applicable to actual production into a manufacturing process file.

According to another aspect, the present disclosure provides an electronic device including a memory and a processor, wherein the memory stores instructions executable by the processor, and the instructions, when executed by the processor, cause the processor to implement the method according to the embodiments of the present disclosure.

According to another aspect, the present disclosure provides a non-transitory computer readable storage medium storing computer instructions, wherein the computer instructions are configured to cause a computer to implement the method according to the embodiments of the present disclosure.

According to another aspect, the present disclosure provides a computer program product, including a computer program, wherein the computer program, when executed by a processer, implements the method according to the embodiments of the present disclosure.

According to another aspect, the present disclosure provides a method of manufacturing a display panel, including a physical manufacturing process and a digital processing process, wherein:
in the physical manufacturing process, at least one process of the display panel is performed, so as to obtain actual process data and actual measurement data;
in the digital processing process, the method according to the embodiments of the present disclosure is performed by using a process model and a measurement model which are generated based on the actual process data and the actual measurement data, so as to verify whether simulation process data is applicable to actual production.

For example, at least one process of the display panel in the physical manufacturing process includes: sequentially performing a pre-measurement operation, a preparation operation, a loading process data operation, a processing operation, and a post-measurement operation, wherein the actual process data is loaded in the loading process data operation, and the actual measurement data is generated in at least one of the pre-measurement operation, the processing operation and the post-measurement operation.

For example, the manufacturing method further includes applying the simulation process data as the actual process data to the loading process data operation in the physical manufacturing process, in response to verifying that the simulation process data is applicable to actual production.

For example, the manufacturing method further includes: re-performing the physical manufacturing process to generate new actual process data and new actual measurement data; and updating the process model and the measurement model based on the new actual process data and the new actual measurement data.

### BRIEF DESCRIPTION OF THE DRAWINGS

FIG. 1 is a flowchart of a method of verifying process data of a display panel according to an embodiment of the present disclosure;

FIG. 2A is a flowchart of a method of verifying process data of a display panel according to another embodiment of the present disclosure;

FIG. 2B is a schematic diagram of a method of manufacturing a display panel according to an embodiment of the present disclosure;

FIG. 3 is a schematic diagram of a process of verifying lithography process data according to an embodiment of the present disclosure;

FIG. 4 is a flowchart of generating simulation process data for lithography process according to an embodiment of the present disclosure;

FIG. 5A and FIG. 5B are schematic diagrams of a test pattern generation function in a lithography design simulation according to an embodiment of the present disclosure;

FIG. 5C is a schematic diagram of a layout Boolean operation function in a lithography design simulation according to an embodiment of the present disclosure;

FIG. 5D and FIG. 5E are schematic diagrams of a process window analysis function in a lithography design simulation according to an embodiment of the present disclosure;

FIG. 5F is a schematic diagram of a reflectivity analysis function in a lithography design simulation according to an embodiment of the present disclosure;

FIG. 5G is a schematic diagram of a lithography optical imaging simulation function in a lithography design simulation according to an embodiment of the present disclosure; and

FIG. 6 is a block diagram of an electronic device for implementing a method of verifying process data of a display panel according to an embodiment of the present disclosure.

### DETAILED DESCRIPTION OF EMBODIMENTS

In order to make purposes, technical solutions, and advantages of embodiments of the present disclosure clearer, technical solutions in some embodiments of the present disclosure will be described clearly and completely in combination with accompanying drawings. Obviously, the described embodiments are only part of the embodiments of the present disclosure, not all of them. Based on the embodiments of the present disclosure provided, all other embodiments obtained by those of ordinary skilled in the art without creative labor, fall within scope of protection of the present disclosure. It should be noted that throughout the drawings, same elements are represented by same or similar reference signs. In the following description, some specific embodiments are only for descriptive purposes and should not be understood as limiting the present disclosure, but rather as examples of the embodiments of the present disclosure. When it may cause confusion in understanding of the present disclosure, conventional structures or configurations will be omitted. It should be noted that a shape and size of each component in the drawings do not reflect the true size and proportion, but only represent contents of the embodiments of the present disclosure.

Unless otherwise defined, the technical or scientific terms used in the embodiments of the present disclosure shall have the usual meaning understood by those of ordinary skilled in the art. The terms “first”, “second”, and similar terms used in the embodiments of the present disclosure do not indicate any order, quantity, or importance, but are only used to distinguish different components.

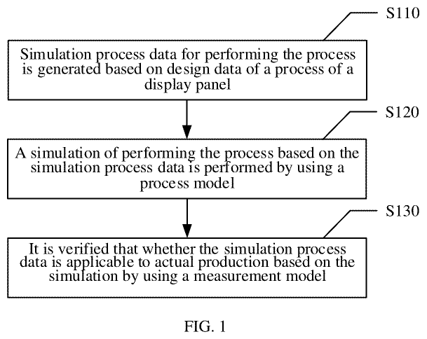

FIG. 1 is a flowchart of a method of verifying process data of a display panel according to an embodiment of the present disclosure.

As shown in FIG. 1, the method of verifying process data may include operations S110 to S130.

In operation S110, simulation process data for performing the process is generated based on design data of a process of a display panel.

For example, the design data may include a design file. The design file includes information related to a design of the process of the display panel, such as but not limited to design drawings and design parameters of one or more components to be used or generated in a manufacturing process of the display panel. In some embodiments, the design data may also include other data related to a design of the display panel, such as parameters, conditions, etc. related to the manufacturing process of the display panel. By taking a lithography process of the display panel as an example, the design data may include at least one of the following data involved in the lithography process: a design pattern of a mask plate, an exposure parameter setting information, a resist parameter setting information, and a development parameter setting information. Various design data input by a user may be received through a user interaction interface, and corresponding process data may be generated as simulation process data based on the received design data. For example, a computer may select and segment the received design pattern of the mask plate to obtain a test pattern suitable for designers to view. In some embodiments, the computer may also generate an exposure process parameter based on the exposure parameter setting information, generate a resist process parameter based on the resist parameter setting information, and generate a highlight process parameter based on the development parameter setting information. In some embodiments, the computer may also generate various simulation results for designers to view through model deduction or calculation based on the received various design data. Designers may adjust the design data through the interaction interface based on the simulation results. The computer may regenerate simulation process data based on the design data adjusted by the designer. Through repeated adjustments, simulation process data that better meets practical requirements may be ultimately obtained. This process is referred to as a product design simulation process.

The product design simulation process may be implemented through simulation design software. For example, the simulation software may select a photoresist according to requirements of the process. The simulation software may simulate and design images of the mask plate based on desired lithography images. The simulation software may also simulate a photochemical reaction of the photoresist after being irradiated with light (exposed to light). An internal structure of an irradiated part of the photoresist and an internal structure of a non-irradiated part of the photoresist will undergo different chemical changes, so that a dissolution rate of the irradiated part in a developer is very different from a dissolution rate of the non-irradiated part in a developer. The simulation software may simulate the characteristics of the photoresist, combined with the patterns of the mask plate, to obtain images corresponding to the mask plate formed on the photoresist. In addition, the simulation software may simulate an exposure process by using a high-precision alignment lithography machine to perform simulating different exposure times, different exposure light sources, different types of photoresists, different viscosities and thicknesses of photoresists and the like. For example, the process data used by the simulation software in simulating the lithography process may be output as corresponding simulation process data, such as a mask plate pattern, an exposure time, an exposure light source, a type of photoresist, a viscosity and a thickness of photoresist, for the lithography process.

In operation 120, a simulation of performing the process based on the simulation process data is performed by using a process model.

In operation 130, it is verified whether the simulation process data is applicable to actual production is based on the simulation by using a measurement model.

The process model is constructed based on actual process data generated in an actual manufacturing process of the display panel, and the measurement model is constructed based on actual process data and actual measurement data which are generated in the actual manufacturing process of the display panel.

For example, the actual process data and the actual measurement data may be historical data generated in the actual manufacturing process of the display panel. Due to an influence of a process fluctuation of device in the actual manufacturing process, the actual process data and the actual measurement data are fluctuating. Therefore, the process model constructed based on the actual process data and the measurement model constructed based on the actual process model and the actual measurement data may indicate the process fluctuation of device in the actual manufacturing process. According to the process model and the measurement model, a virtual verification simulation may be performed on the simulation process data, so that process data reflecting an actual manufacturing situation may be obtained.

For example, the actual measurement data includes data measured before starting the process and data measured after starting the process. The data measured before staring of the process may include current static data of a process device and raw material data for manufacturing the display panel, etc. The data measured after starting the process may include current operating data of the process device and sample data, etc.

The verification method of the embodiment of the present disclosure is applicable to the process in the manufacturing process of the display panel. The simulation process data for performing the process may be generated based on design data, and the feasibility of the simulation process data may be virtual verified based on the process model and the measurement model which are constructed based on actual data, so as to interconnect design simulation data of the display panel with virtual verification simulation data, thereby realizing complete process digital twins. Compared to manual verification in traditional technology, time of designing and verifying the display panel is shortened.

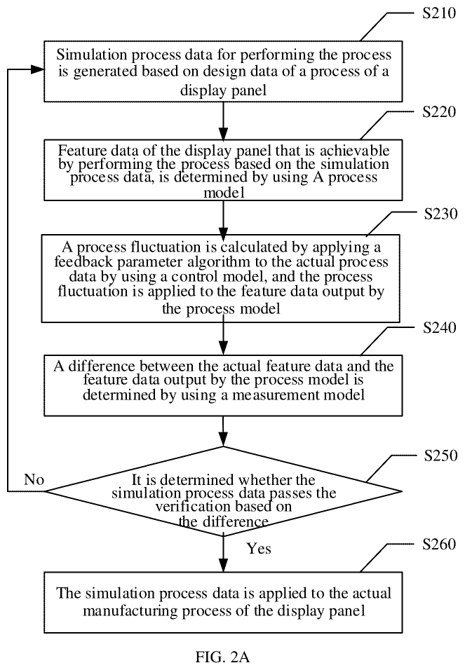

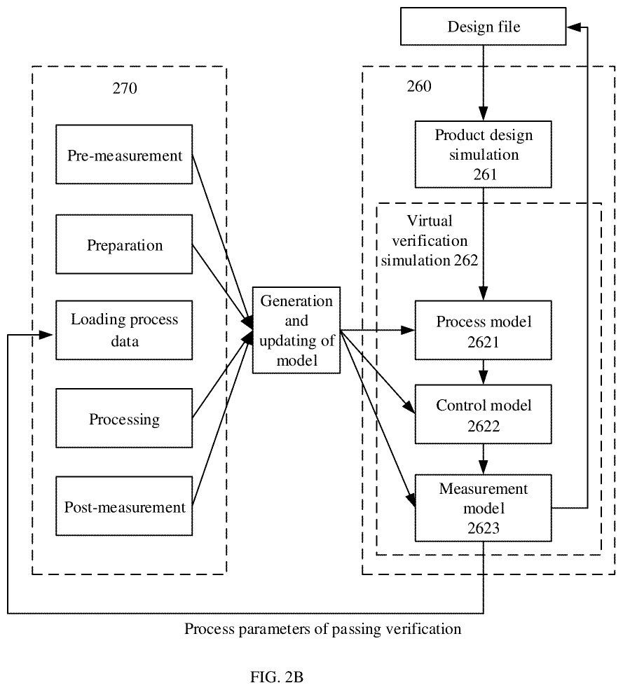

FIG. 2A is a flowchart of a method of verifying process data of a display panel according to another embodiment of the present disclosure. As shown in FIG. 2A, the method of verifying process data may include operations S210 to S260.

In operation S210, simulation process data for performing a process of a display panel is generated based on design data of the process.

For example, the simulation software may be used to generate simulation process data for performing the process based on the design data of the process of the display panel. For example, a user may start an interface of the simulation software and set parameters in the interface, so that the computer generates simulation process data for performing the process of the display panel based on the design data of the display panel and the parameters set by the user. The simulation process data may include various simulation process parameters, such as but not limited to a GDS design diagram, a dose, a critical dimension (CD), a mechanical design diagram, a circuit design pattern, a structural design diagram, an exposure wavelength, a spectral specific gravity, a light source type, an aperture value, a photoresist thickness, a developer concentration, a soft-baking temperature, a pre-baking temperature and time, etc. As an example, a computer may generate a test pattern based on a design diagram of the display panel, and generate various simulation process parameters such as the exposure wavelength, the aperture value, the photoresist thickness and the developer concentration based on the parameters set by the user. The parameters input by the user may represent the user's requirements on the specification of the display panel. In some embodiments, a simulation result diagram may be generated based on the test pattern and/or generated various process parameters for the user to view. The user may adjust the input based on the simulation result diagram, and the computer may correspondingly adjust the generated various process parameters based on the adjusted user input. The user may also debug the simulation process on the interface of the simulation software. The simulation process of the simulation software may simulate various environmental parameters, device parameters, material parameters, chemical reactions and physical reactions of the process, and perform a simulation calculation in a manner of numerical calculation by using a solver.

For example, the design data of the display panel may include the design data of the process of the display panel. The process of the display panel includes a backplane manufacturing process, a vapor plating packaging process, a module process and the like. The design data of the display panel may include a GDS design diagram, a circuit design layout, a structural design diagram, a mechanical design diagram, a dose, a critical dimension and the like. In different stages of the process, different simulation software may be used. For each type of process, the simulation software will generate corresponding simulation process parameters. The types of simulation process parameters corresponding to each process may be the same or different. For example, for a lithography process in the backplane manufacturing process, the design data input to the simulation software may include the GDS design diagram, the critical dimension, and the recommended doses.

The above process may be referred to as a display panel design simulation process. After generating simulation process data through the above display panel design simulation, the process of performing the process based on the simulation process data may be simulated based on a mathematical model, and it may be verified whether the simulation process data is applicable to actual production based on the simulation. This process is referred to as a virtual verification simulation. For example, the simulation process data output by the simulation software may be implemented as an input of the virtual verification simulation process. The verified simulation process data applicable to actual production may be formed into a manufacturing process file. The manufacturing process file may be represented in form of drawings, sketches, textual content, or tables. The process data included in the manufacturing process file may be process data applicable to actual production. The manufacturing process file may also include a process regulation and a process card. The process regulation may include operating methods of the process, and the process card may include process parameters and process standards involved in the process. For example, the manufacturing process file includes simulation process data that meets requirements of the display panel after verifying the simulation process data output by the simulation software, including the dose information, the exposure wavelength, the spectral specific gravity, the light source type, the aperture value, the photoresist thickness, the developer concentration, the soft-baking temperature, the pre-baking temperature and time, etc.

After obtaining the simulation process data, it is required to perform the virtual verification simulation on the simulation process data. For example, the process of performing the process based on the simulation process data is simulated based on a data model, and it is verified whether the simulation process data is applicable to actual production based on the simulation. The mathematical model may include a process model and a measurement model. In some embodiments, the mathematical model may also include a control model. The virtual verification simulation will be described below in combination with steps S220 to S240.

In operation S220, a process model is used to determine feature data of the display panel that is achievable by performing the process based on the simulation process data.

The process model may be a process mechanism model constructed based on the actual process data. The process model may take simulation process data as an input and take the feature data of the display panel as an output, and simulate performing of the process by establishing a linear or nonlinear relationship between the input and the output. For example, according to the process mechanism model (such as a physical model of lithography, a drift diffusion model of etching and chemical vapor deposition), an accurate mathematical formula is established to identify the relationship between the input and the output (linear or nonlinear). Then the mathematical formula is optimized through experiments or mass manufacturing process parameters, so as to obtain the process model. Thus, the process model may generate feature data corresponding to any one of the processes of the display panel based on the linear relationship or the nonlinear relationship between various simulation process parameters and feature data.

In operation S230, a process fluctuation is calculated by applying a feedback parameter algorithm to the actual process data by using a control model, and the process fluctuation is applied to the feature data output by the process model.

The control model may be a fluctuation law model constructed based on the actual process data. The control model is used to apply a process fluctuation calculated based on the actual process data to a simulation result to generate an adjusted simulation result. The control model may simulate the operational logic of the process to be simulated and realize a management of the model state (data filtering, control logic). The control model may select a feedback parameter algorithm in an optimization process control model to calculate the process fluctuation based on the process data and/or the measurement data generated in the actual manufacturing process. The feedback parameter algorithm may automatically correct the process fluctuation. The operational logic may be that a model is abstracted from a business process by a process engineer. The model state management may include filtering sources of the process data required for each business process. Changing the business process requires an adjustment such as adding, deleting, changing, and querying of the control logic. The feedback parameter algorithm may include one of a moving average algorithm, a weighted moving average algorithm, and an exponential moving average algorithm.

In operation S240, a measurement model is used to perform a difference comparison between the actual feature data and the feature data output by the process model.

The measurement model may be a statistical model constructed based on the actual measurement data and the actual process data. For example, the measurement model may be constructed by a machine learning algorithm (SVM, decision tree, random forest, logical regression, Bayes, etc.) based on the actual measurement data. The measurement model is used to verify whether the simulation process data is applicable to actual production by comparing a simulation result of the simulation process data with the actual measurement data of the actual process data.

For example, the measurement model may determine, among the actual process data, data in the actual process data, a similarity of which between the data in the actual process data and the simulation process data is higher than a preset similarity threshold as similar process data, and determine, among the actual measurement data, feature data of the display panel obtained by actual performing the process by using similar process data as actual feature data. Then, the measurement model may compare the actual feature data mentioned above with the feature data, which is generated by the process model and applied with the process fluctuation by the control model. If the difference between the actual feature data and the feature data is less than a preset difference threshold, it is determined that the simulation process data is applicable to actual production.

Although it is determined whether the difference meets predetermined requirements by comparing the difference with the threshold in the above embodiments determine, embodiments of the present disclosure are not limited to this. It is also possible to determine whether the difference meets the predetermined requirements based on other calculation methods, which will not be repeated here.

In operation S250, it is determined whether the simulation process data passes the verification based on a comparison result. If the simulation process data passes the verification, operation S260 is performed, otherwise the process returns to step S210, so that the user adjusts the design data or adjusts parameter settings.

For example, if the feature data obtained by simulation calculation based on simulation process parameters in operation S230 matches the feature data of the structure manufactured using process parameters similar to the simulation process parameters in the actual manufacturing process, it is determined that the simulation process data passes the verification, otherwise it is determined that the simulation process data fails to pass the verification. If the verification result satisfies a manufacturing process standard required by the product, it may be determined that qualified display panels that meet the predetermined requirements may be generated by using the simulation process data obtained by a product design simulation of the display panel in a real physical process device. If the verification result does not satisfy the manufacturing process standard, it may be determined that display panels that might not meet the predetermined requirements would be generated by using the simulation process data obtained by the product design simulation of the display panel in the real physical process device. In this case, it is required to modify the design data of the display panel to obtain the verification result of the manufacturing process standard that meets requirements of the display panel.

The lithography process is taken as an example. Assuming that an exposure process parameter A1, a resist process parameter A2, and a development process parameter A3 are generated in operation S210, the lithography process is simulated based on process parameters A1, A2 and A3 in operation S220. The feature data such as shape, size of a lithography pattern are obtained by calculation. In operation S230, a process fluctuation is added to the feature data simulated in operation S220. Then, in step S240, among the various process parameters used in the actual manufacturing process, a measurement model may be used to determine an exposure process parameter that differs from A1 by a factor less than a preset threshold, a resist process parameter that differs from A2 by a factor less than a preset threshold, and a development process parameter that differs from A3 by a factor less than a preset threshold. If such process parameters are found, such as exposure process parameter B1, resist process parameter B2, and development process parameter B3 in which the difference between A1 and B1, the difference between A2 and B2, and the difference between A3 and B3 are less than the preset threshold, the actual process data B1, B2 and B3 are determined as the similar process data of the simulation process data A1, A2 and A3. Then, among the actual measurement data, the feature data of the photolithography pattern, such as the shape and size of the photolithography pattern, which are measured in a case of performing an actual photolithography process based on the exposure process parameter B1, the resist process parameter B2, and the development process parameter B3, are determined as the actual feature data. Then, in step S250, the actual feature data (i.e. the shape, size, etc. of the measured lithography pattern) is compared with the feature data provided in step S230 (i.e. the size, shape, etc. of the lithography pattern obtained by virtual simulation of the process model). If the difference between the actual feature data and the feature data is less than the preset threshold, it is determined that a photolithographic pattern obtained by virtual simulation based on the simulation process parameters A1, A2 and A3 is substantially consistent with a photolithographic pattern obtained by performing photolithographic processes based on similar actual process parameters B1, B2 and B3 in the actual manufacturing process. Therefore, it may be determined that the simulation process parameters A1, A2, and A3 are feasible in actual manufacturing, that is, the simulation process parameters passes the verification. On the contrary, if the difference between the photolithography pattern obtained by virtual simulation based on simulation process parameters A1, A2, and A3 and the photolithography pattern obtained in the actual manufacturing process based on process parameters B1, B2, and B2 is too large to exceed an acceptable range, it is determined that it is not practical to applying the simulation process parameters A1, A2, and A3 to actual manufacturing, that is, the simulation process parameters do not pass the verification.

In operation S260, the simulation process data is applied to the actual manufacturing process of the display panel.

For example, after the display panel design is verified and simulated virtually, if the standard is met, the design data is imported into the real physical process device. If the virtual verification simulation data does not meet conditions of actual physical process manufacturing, the design data of the display panel may be modified in time. By using the virtual verification method, the simulation process data that meet the conditions of the actual physical process manufacturing may be applied to the actual manufacturing process of the display panel, so as to shorten the design verification time of the display panel and accelerate the launch speed of the new display panel.

In some embodiments, operation S230 may be optional. For example, in some embodiments, operation 230 may be omitted to improve processing speed. In the case of omitting operation S230, in operation S240, the measurement model may compare the feature data of the display panel output by the process model in operation S220 with the actual feature data, so as to determine whether the simulation process parameters pass the verification.

In embodiments of the present disclosure, it is also possible to update the actual process data and the actual measurement data, and update the mathematical model, for example at least one of the above process model, the measurement model, and the control model, based on the updated actual process data and the updated actual measurement data.

For example, the actual process data and the actual measurement data which are generated by the actual manufacturing process may be obtained periodically or obtained again after completing the actual manufacturing process, so as to be added into the existing actual process data and the existing actual measurement data or replace them, thereby achieving the updating of the actual process data and the actual measurement data. The mathematical model may be adjusted based on the updated actual process data and the updated actual measurement data. In the virtual verification simulation process, the updated mathematical model nay be used to verify the simulation process data generated during the display panel design simulation process.

In some embodiments, manufacturing parameters may be optimized based on the verification result. In some embodiments, fault prediction maintenance and defect prediction may be performed based on the verification result.

FIG. 2B is a schematic diagram of a method of manufacturing a display panel according to an embodiment of the present disclosure. As shown in FIG. 2B, the manufacturing of the display panel includes a digital processing process 260 and a physical manufacturing process 270.

The digital processing process 260 is also referred to as a digital process, which is a virtual process that includes display panel design simulation 261 and virtual verification simulation 262. The physical manufacturing process 270 is also referred to as a physical process, which is a real process. The physical manufacturing process 270 includes a pre-measurement, a preparation operation, a loading process data, a processing, and a post-measurement process. The data generated by the physical manufacturing process 270 may include actual process data and actual measurement data. In the physical manufacturing process 270, the pre-measurement process generates actual measurement data before the process, and the post measurement process generates actual measurement data after the process. The preparation process and the processing may generate process data. The actual data generated by the physical manufacturing process 270 may be used to construct and optimize the mathematical model required for the digital processing process 260.

The mathematical model constructed in the process of virtual verification simulation 262 may include a process model 2621, a control model 2622, and a measurement model 2623. The process model 2621 may be constructed based on the actual process data, the control model 2622 may also be constructed based on the actual process data, and the measurement model 2623 may be constructed based on the actual measurement data and the actual process data.

In embodiments of the present disclosure, the simulation process data generated by the process of product design simulation 261 in the digital processing process 260 includes various simulation process parameters. In the virtual verification simulation 262, the process model 2621 may be used to determine the feature data of the display panel that may be obtained in a case of performing the process based on the simulation process data. The control model 2622 may be used to apply a feedback parameter algorithm to the actual process data to calculate a process fluctuation and apply the process fluctuation to the feature data output by the process model 2621, so as to obtain an adjusted feature data. The measurement model 2623 may be used to determine a difference between the adjusted feature data and the actual feature data, and determine that the simulation process data passes the verification and is applicable to actual production, in response to a difference between the actual feature data and the feature data output by the process model 2621 being less than a preset difference threshold. The measurement model 2623 determines, among the actual process data, the actual process data having a similarity higher than a preset similarity threshold with respect to the simulation process data, as similar process data, and determines, among the actual measurement data, feature data of the display panel which is obtained by actually performing the process based on the similar process data, as actual feature data.

For example, for dose and feature size, there is a linear relationship between dose and feature size, following a constraint of y=kx, where y is the dose, x is the feature size, k may be a linear parameter, and the linear parameter may be summarized based on historical experience. In a case that the simulation process data is the dose, the process model 2621 may generate a corresponding feature size based on the linear relationship y=kx. According to different processes and mechanisms, parameter k may be linear or nonlinear.

For example, the control model 2622 may be a fluctuation law model formed according to the process fluctuation of the device.

For example, the feedback parameter algorithm includes a moving average algorithm, a weighted moving average algorithm, and an exponential moving average algorithm. One of the moving average algorithm, the weighted moving average algorithm, and the exponential moving average algorithm may be selected as an optimization algorithm.

For example, the moving average algorithm includes calculating an average value of process parameters for a plurality of consecutive cycles according to an equation:

$$MA = \frac{{C}_{1} + {C}_{2} + ⋯ + {C}_{n}}{n}$$

where each of C₁, C₂, . . . Cₙ is a value of the process parameter of a respective cycle, and n is an integer greater than 1.

For example, the weighted moving average algorithm includes one of a doomsday weighted algorithm, a linear weighted algorithm, a trapezoidal weighted algorithm, and a square coefficient weighted algorithm.

For example, the doomsday weighted algorithm includes calculating a weighted average value of process parameters of a plurality of consecutive cycles according to an equation:

$$WMA = \frac{{C}_{1} + {C}_{2} + ⋯ + {C}_{n} \times 2}{n + 1}$$

where each of C₁, C₂, . . . Cₙ is a value of the process parameter of a respective cycle, and n is an integer greater than 1.

For example, the linear weighted algorithm includes calculating a weighted average value of process parameters of a plurality of consecutive cycles according to an equation:

$$WMA = \frac{{C}_{1} \times 1 + {C}_{2} \times 2 + ⋯ + {C}_{n} \times n}{1 + 2 + 3 + ⋯ + n}$$

where each of C₁, C₂, . . . Cₙ is a value of the process parameters of a respective cycle, and n is an integer greater than 1.

For example, the trapezoidal weighted algorithm includes calculating a weighted average value of process parameters of a plurality of consecutive cycles according to an equation:

$$WMA = \frac{( {C}_{1} + {C}_{2} ) \times 1 + ( {C}_{2} + {C}_{3} ) \times 2 + ⋯ + ( {C}_{n - 1} + {C}_{n} ) \times ( n - 1 )}{2 \times 1 + 2 \times 2 + 2 \times 3 + ⋯ + 2 \times ( n - 1 )}$$

where each of C₁, C₂, . . . Cₙ is a value of the process parameter of a respective cycle, and n is an integer greater than 1.

For example, the square coefficient weighted algorithm includes calculating a weighted average value of process parameters of a plurality of consecutive cycles according to an equation:

$$WMA = \frac{{C}_{1} \times {1}^{2} + {C}_{2} \times {2}^{2} + ⋯ + {C}_{n} \times {n}^{2}}{{1}^{1} + {2}^{2} + {3}^{2} + ⋯ + {n}^{2}}$$

where each of C₁, C₂, . . . Cₙ is a value of the process parameter of a respective cycle, and n is an integer greater than 1.

For example, the exponential moving average algorithm includes calculating a weighted average of process parameters of a plurality of consecutive cycles according to an equation:

$$EMA = \frac{{C}_{1} ( 1 + α ) {C}_{2} + {( 1 + α )}^{2} {C}_{3} … + {( 1 + α )}^{n} {C}_{n}}{1 + ( 1 + α ) + {( 1 + α )}^{2} + ⋯ + {( 1 + α )}^{n}}$$

where each of C₁, C₂, . . . Cₙ is a value of the process parameter of a respective cycle, n is an integer greater than 1, and α is a weighted index.

For example, the measurement model 2623 may be a statistical model of device measurement formed by historical measurement data of the device.

The historical measurement data is real measurement data generated in the actual process, and the real measurement data is constructed based on the measurement model. By comparing the difference between the adjusted feature data generated by the control model 2622 and the actual feature data by the measurement model 2623, whether the simulation process data passes the verification is determined based on the comparison result. The constructed measurement model 2623 may be used in a verification stage of the virtual verification simulation. Since the virtual verification stage does not perform actual manufacturing, it is required to perform a virtual measurement by the measurement model 2623.

For example, after a virtual verification simulation of a backplane manufacturing process is completed, it is determined whether the simulation process parameters output from the virtual verification simulation are matched with historical actual process data or not. If yes, the simulation process data is considered to pass the verification, otherwise it is considered to fail to pass the verification.

Based on the method of verifying the process data of the display panel in the embodiments of the present disclosure, the present disclosure may also provide a method of manufacturing a display panel.

For example, the method of manufacturing the display panel includes a physical manufacturing process (such as the physical manufacturing process 270 mentioned above) and a digital processing process (such as the digital processing process 260 mentioned above).

In the physical manufacturing process, at least one process of the display panel may be performed to obtain actual process data and actual measurement data. For example, in the physical manufacturing process, a pre-measurement operation, a preparation operation, a loading process data operation, a processing operation, and a post-measurement operation may be sequentially performed. In the loading process data operation, the actual process data is loaded, and in at least one of the pre-measurement operation, the processing operation and the post-measurement operation, the actual measurement data is generated.

In the digital processing process, the process model and the measurement model which are generated based on the actual process data and the actual measurement data may be used to perform the verification method of any of the above embodiments to verify whether the simulation process data is applicable to actual production. In some embodiments, it is also possible to apply the simulation data as the actual process data to the loading process data operation in the physical manufacturing process, in response to verifying that the simulated process data is applicable to actual production.

For example, the actual measurement data includes data measured before starting the process and data measured after starting the process, such as the measurement data obtained by the pre-measurement operation of the physical manufacturing process 270 and the measurement data obtained by the post-measurement operation of the physical manufacturing process 270.

For example, in the method of manufacturing the display panel, the physical manufacturing process may be performed again to generate new actual process data and new actual measurement data, and the mathematical model may be updated based on the new actual process data and the new actual measurement data. After performing the pre-measurement operation, the preparation operation, the loading process data operation, the processing operation and the post-measurement operation of the physical manufacturing process 270 again, the simulation data of the actual manufacturing of the physical manufacturing process 270 will be applied as the actual process data to the digital processing process 260 to obtain updated actual process data and updated actual measurement data, and the mathematical model will be updated based on the updated actual process data and the updated actual measurement data.

Through the embodiments of the present disclosure, the digital process constructs and adjusts data models based on actual process data provided by the physical process, so as to achieve data sharing and interaction between the digital process and the physical process. In the digital process, a data interconnection and interworking between the display panel design simulation and the virtual verification simulation forms a complete process of process digital twins, so as to form a process digital twins closed-loop of product design—product design simulation—virtual verification simulation, thereby achieving an interconnection and interworking of virtual data and actual data. The result of the product design simulation is verified through the virtual verification simulation and an optimization direction of design data of the display panel is provided, so as to modify the design data of the display panel in time, reducing the design verification time of the display panel and accelerating the launch speed of the new display panel.

The process of the display panel may include a backplane manufacturing process. The backplane manufacturing process may include coating, lithography, and etching processes. The coating process includes sputter and plasma enhanced chemical vapor deposition (PECVD). The sputtering process deposit a metal film layer in a principle of physical sputtering. The PECVD deposits a semiconductor or non-metallic film layer through chemical vapor deposition. The lithography process includes a track process and an aligner process. In the track process, photosensitive photoresist is coated on the substrate, and after exposure is completed, the exposed photoresist is developed. The lithography process uses ultraviolet light to photosensitive an unmasked photoresist, so as to complete the exposure. The etching process includes dry etching, wet etching, stripping, and cleaner. The dry etching removes non-metallic or metallic film layer through reactive gas dry etching. The wet etching removes a metallic film layer by using a chemical solution, e.g. through acid wet etching. The stripping process peels off the exposed photoresist by using a chemical solution. The cleaner process cleans the film layer before deposition.

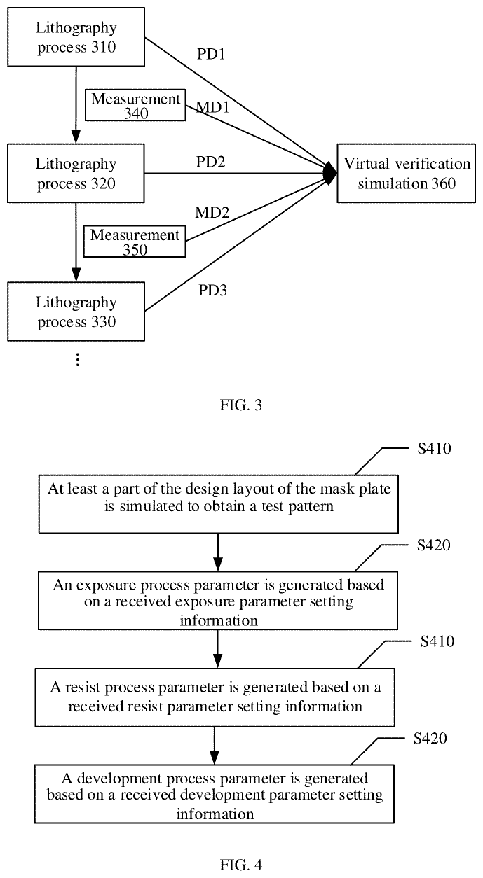

FIG. 3 is a schematic diagram of a virtual verification simulation according to an embodiment of the present disclosure.

As shown in FIG. 3, a physical lithography process includes a plurality of lithography processes 310, 320 and 330. After each lithography process, a measurement operation may be performed to obtain actual measurement data. For example, after the lithography process 310, a measurement operation 340 is performed, and after the lithography process 320, a measurement operation 350 is performed. The process data generated by each lithography process and the measurement data generated by each measurement operation may be obtained for constructing the mathematical model in the virtual verification simulation.

For example, the lithography process 310 generates process data PD1, the measurement operation 340 generates measurement data MD1, then the lithography process 320 in a next cycle generates process data PD2, the measurement operation 350 generates measurement data MD2, then the lithography process 330 in a next cycle generates process data PD3, and so on. The process data generated based on the lithography process and the measurement data generated by the measurement for the lithography process may be used to construct the measurement model in the virtual verification simulation 360. In some embodiments, these process data and measurement data may also be used for adjusting and optimizing the mathematical model.

FIG. 4 is a flowchart for generating simulation process data for lithography process according to an embodiment of the present disclosure.

The process of the display substrate includes a lithography process used to form a film layer in a backplane manufacturing process. The lithography process may include mask design, exposure, resist, and a development process. The design data includes a design pattern of a mask. The steps of generating simulation process data of the lithography process based on the design data of the display panel may include at least one of operations S410 to S440.

In operation S410, at least some regions of the design pattern of the mask plate are performed simulation to obtain a test pattern.

For example, in a process of mask design, the design data of the mask is imported into the simulation software, a position of the target graphic required to be etched may be defined on the substrate for selection and simulation, so as to generate a test pattern.

In operation S420, an exposure process parameter is generated based on a received exposure parameter setting information.

For example, in the exposure process, the exposure process parameter of the exposure machine device is generated in simulation software. The exposure process parameter includes at least one of the following: numerical aperture, wavelength, coherence factor, lighting type, exposure magnification, and focus position, etc.

In operation S430, a resist process parameter is generated based on a received resist parameter setting information.

For example, in the resist process, the resist process parameter generated includes at least one of the following items: type of photoresist, thickness of photoresist and development rate of photoresist, concentration distribution of substrate material and photosensitive compound PAC.

In operation S440, a development process parameter is generated based on a received development parameter setting information.

In the embodiments of the present disclosure, the method of generating lithography process simulation process data includes, on a basis of operating S410 to S440, performing lens projection simulation on the test pattern based on the exposure process parameter to obtain aerial image data, and generating graphic data of a developed film layer based on the development process parameter.

For example, on the basis of operations S410 to S440, the steps of generating simulation process data of photolithography process based on design data of the display panel may also include representing at least one of the aerial image data and graphic data through a user interaction interface, receiving user input, and adjusting at least one of the exposure process parameter, the etching resist process parameter and the development process parameter based on user input.

For example, in the exposure process, the aerial image data may be exported based on a aerial image distribution after lens projection. In the development process, the development parameter is imported into the development module of the simulation software, the developed patterns may be output. In the user interaction interface, the aerial image data and/or the image data are represented, so that users may determine whether the aerial image data and/or the image data meet conditions based on the represented aerial image data and/or the represented image data. If the conditions are not met, relevant settings are input to adjust at least one of the exposure process parameter, the resist process parameter, and the development process parameter.

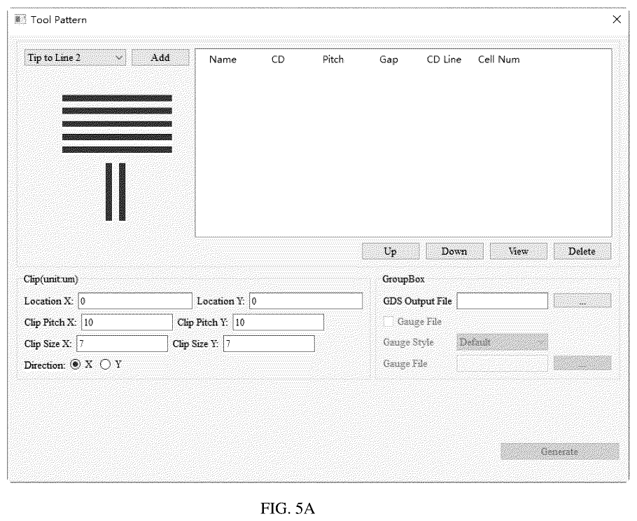

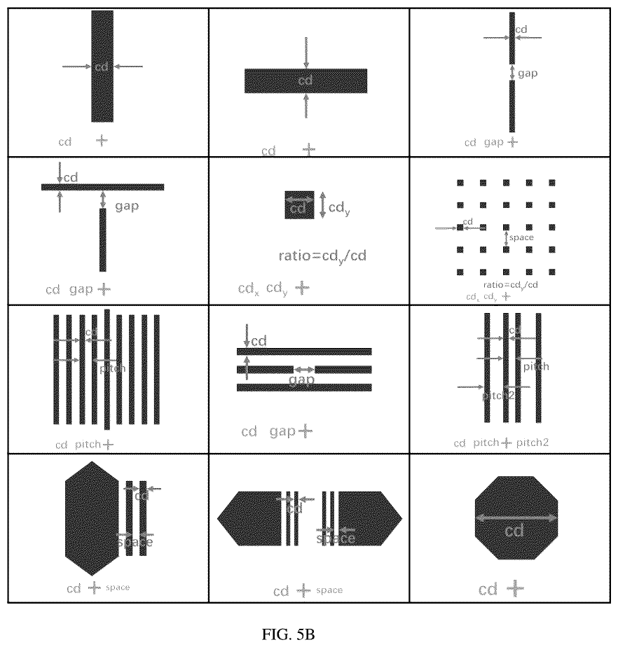

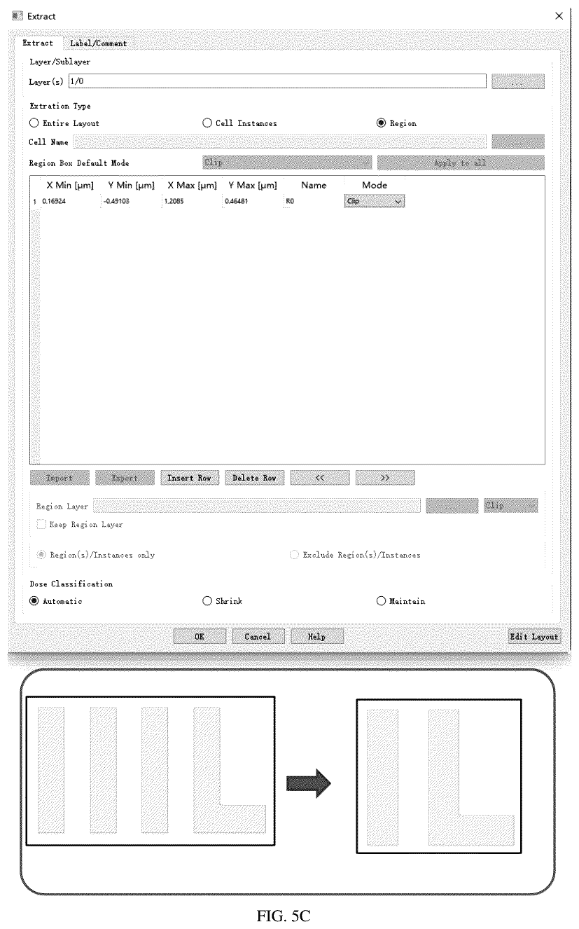

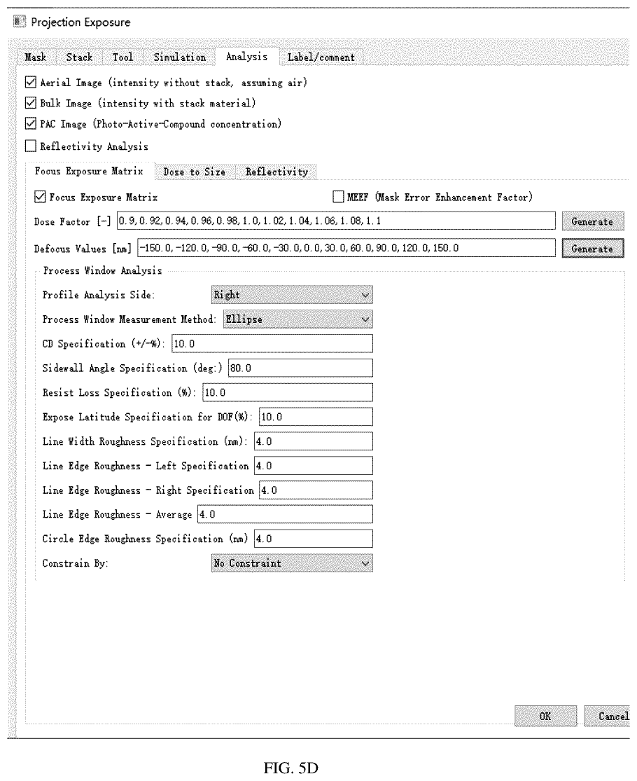

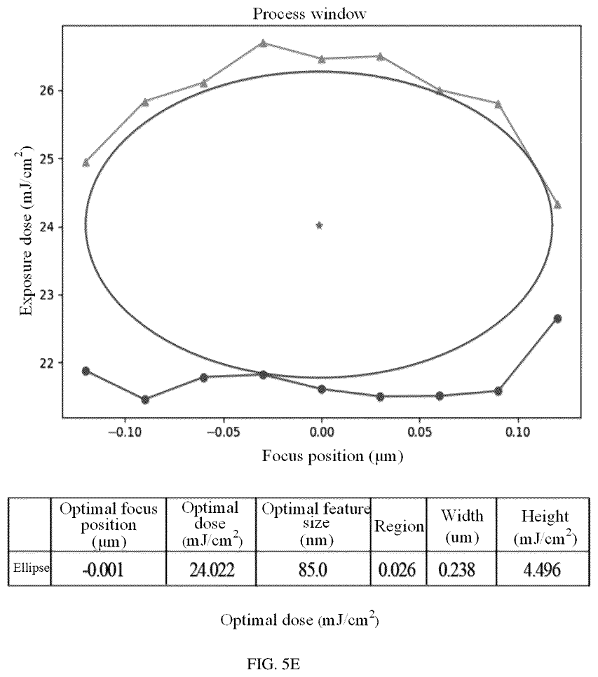

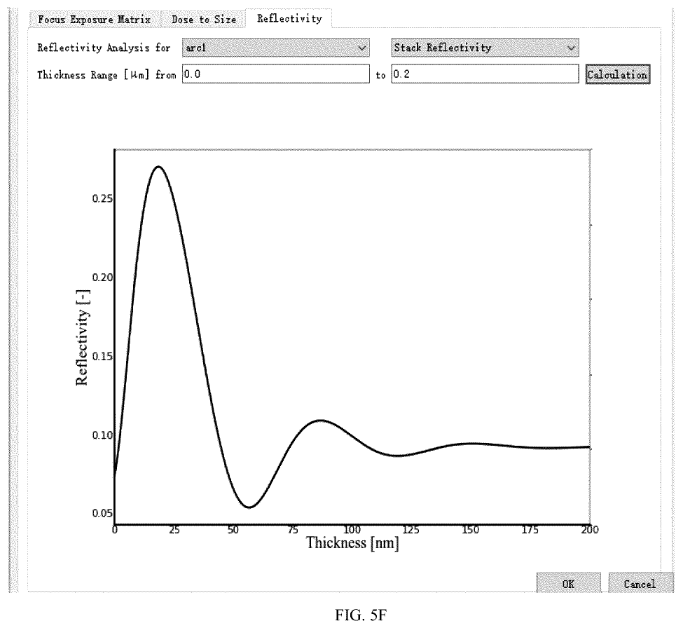

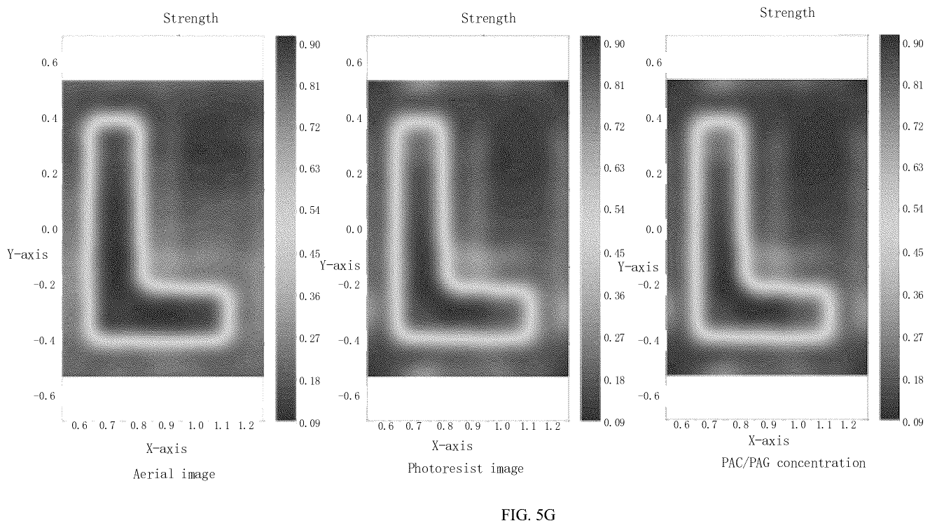

FIG. 5A and FIG. 5B are schematic diagrams of a test pattern generation function in a lithography design simulation according to an embodiment of the present disclosure. FIG. 5C is a schematic diagram of a layout Boolean operation function in a lithography design simulation according to an embodiment of the present disclosure. FIG. 5D and FIG. 5E are schematic diagrams of a process window analysis function in a lithography design simulation according to an embodiment of the present disclosure. FIG. 5F is a schematic diagram of a reflectivity analysis function in a lithography design simulation according to an embodiment of the present disclosure. FIG. 5G is a schematic diagram of a lithography optical imaging simulation function in a lithography design simulation according to an embodiment of the present disclosure.

As shown in FIGS. 5A to 5C, at least some regions of the design pattern of the mask plate may be simulated to obtain the test pattern. According to setting rules, a set of regular test images may be generated. Special test patterns may be generated based on specific requirements of users. The interaction interface shown in FIG. 5A is used to represent preset default rules or receive rules input by users based on special requirements. The computer may select and simulate the position of at least a part of the design pattern of the mask plate based on a rule (such as a clip pitch X and a clip size X in an X direction, and a clip pitch Y and a clip size Y in a Y direction), and obtain the test pattern shown in FIG. 5B. As shown in FIG. 5B, the test pattern may contain information such as the feature size cd, the number of graphics in the layout, the space between graphics, the gap between graphics, and the pitch between graphics. As shown in FIG. 5C, in the layout Boolean operation function interface, the test pattern (such as the test pattern shown in FIG. 5B) may be divided into regions or units to be viewed and edited. Boolean operation may be performed on the graphics in the test pattern, and operations such as expanding, shrinking, flipping, and extracting may be performed on the graphics. The functions of compressing and zooming in may be provided in a dynamic range. For example, as shown in FIG. 5C, an original test pattern includes three graphic elements having a shape of “I” and arranged in parallel and one graphic element having a shape of “L”. By performing Boolean operation on the original test pattern, the three graphic elements of shape “I” arranged in parallel are merged to obtain one graphic element having a shape of “I”. Boolean operations may also include subtraction, union, and intersection operations on a plurality of graphic elements.

As shown in FIGS. 5D to 5F, after generating the test pattern, at least one of the exposure parameter setting information, the resist parameter setting information, and the development parameter setting information may be received through the interaction interface. For example, the exposure parameter setting information input by the user may be received through the interface as shown in FIG. 5D. The computer may generate the exposure process parameter based on the received exposure parameter setting information, generate the resist process parameter based on the received resist parameter setting information, and generate the development process parameter based on the received development parameter setting information. As shown in FIG. 5E, based on the various parameter information as set in FIG. 5D, process window analysis may be performed. For example, the computer obtains a lithography process window corresponding to the simulation graphic based on the exposure dose (Dose Factor) and the defocus amount (defocus values). For example, the computer may correlate and analyze the aerial image, the photoresist image (bulk image) and the photosensitive compound concentration distribution image (PAC image) in the exposure simulation process according to the selection. In the exposure simulation process, a exposure focus matrix (exposure dose and defocus amount), a process window measurement method, a CD specification, a sidewall angle specification, a resist less specification, an expose latitude specification and a line edge roughness specification may also be set for process window analysis. The computer simulates the parameters set for the process window analysis, so as to ensure a correct photolithography of the test pattern of the mask. For example, some simulation results of the lithography process window as shown in FIG. 5E, by using an ellipse as a method of measuring the process window, an optimal focus position, an optimal dose and an optimal feature size are obtained by simulation. In addition, parameters such as the shape and limiting conditions of the process window may also be changed, so as to simulate various shapes of process windows and limiting conditions. As shown in FIG. 5F, process stack reflectance analysis may also be performed. For example, for a single photoresist film, a reflectivity of the photoresist film layer may be analyzed, so as to simulate the thicknesses of various single photoresist film layers. For a multilayer structure including a photoresist and an anti-reflection layer, it is also possible to analyze a reflectivity of the substrate and a reflectivity of the multilayer film, so as to simulate the multilayer film structure of the photoresist and anti-reflection layer. Therefore, exposure process parameters, such as numerical aperture, wavelength, coherence factor, illumination type, exposure ratio and focus position, etc., and resist process parameters, such as photoresist type, photoresist thickness and development rate, substrate material and photosensitive compound PAC concentration distribution, may be obtained through photolithography process window simulation and process stack reflectivity simulation.

As shown in FIG. 5G, in some embodiments, lens projection simulation may also be performed on the test pattern based on the exposure process parameter, so as to obtain aerial image data. In some embodiments, graphic data of the developed film layer may also be generated based on the development parameter. For example, in a photolithography optical imaging function interface, simulation modeling may be performed on an aerial image, a photoresist image, and a photosensitive compound/photo acid generator (PAC/PAG) concentration, so as to obtain an optical imaging simulation result as shown in FIG. 5G. For example, for a light source, simulation may be supported for multiple light source illumination methods, multiple light source distributions, single wavelength illumination, and broadband illumination methods. For the mask, two-dimensional thin mask approximation simulation and three-dimensional thick mask analysis simulation may be performed. For simulation methods, Kirchhoff approximation and strictly coupled wave method may be used for simulation. For lenses, wavefront analysis simulation and dry system and immersion system simulation may be performed. For photoresists, an optical effect of photoresist may be modeled using a transfer matrix method. For example, through lithography modeling, the simulation process may be based on the “L” shaped graphic elements of the layout as shown in FIG. 5C for lithography simulation, and based on the exposure process parameter obtained by the simulation, the test pattern may be simulated for lens projection to obtain aerial image data. Then, at least one of the aerial image data and the graphic data may be represented through a user interaction interface to receive user input. For example, by using the user interaction interface to represent at least one of the aerial image data, the photoresist image, and the photosensitive compounds/photo acid generators (PAC/PAG) concentrations as shown in FIG. 5G, for user reference. Then, users may adjust various parameter setting informations through the interaction interface, and the computer may adjust at least one of the exposure process parameter, the resist process parameter, and the development process parameter based on user input.

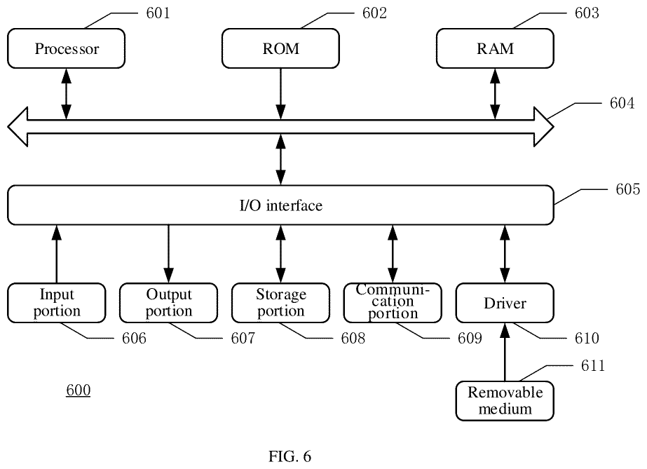

FIG. 6 is a block diagram of an electronic device for implementing a method of verifying process data of a display panel according to an embodiment of the present disclosure. As shown in FIG. 6, the electronic device 600 of the embodiment of the present disclosure includes a processor 601, which may perform various appropriate actions and processes based on a program stored in read-only memory (ROM) 602 or a program loaded from storage section 608 into random access memory (RAM) 603. The processor 601 may include, for example, general-purpose microprocessors (such as CPUs), instruction set processors and/or related chipsets, and/or specialized microprocessors (such as specialized integrated circuits (ASICs)), and so on. The processor 601 may also include onboard memory for caching purposes. The processor 601 may include a single processing unit or multiple processing units for executing different actions of the method flow of the embodiment of the present disclosure.

In RAM 603, various programs and data required for the operation of the electronic device 600 are stored. The processor 601, ROM 602, and RAM 603 are connected to each other through a bus 604. The processor 601 executes various operations of the method flow according to the embodiment of the present disclosure by executing programs in the ROM 602 and/or the RAM 603. It should be noted that the program may also be stored in one or more memories other than the ROM 602 and the RAM 603. The processor 601 may also perform various operations of the method flow according to the embodiment of the present disclosure by executing programs stored in the one or more memories.

According to the embodiment of the present disclosure, the electronic device 600 may also include an input/output (I/O) interface 605, which is also connected to the bus 604. The electronic device 600 may also include one or more of the following components connected to the I/O interface 605: an input portion 606 including a keyboard, mouse, etc., an output portion 607 such as cathode ray tubes (CRTs), liquid crystal displays (LCDs), and speakers, a storage portion 608 such as a hard disk, and a communication portion 609 including network interface cards such as LAN cards, modems, etc. The communication section 609 performs communication processing through a network such as the Internet. A driver 610 is also connected to the I/O interface 605 as desired. Detachable mediums 611, such as magnetic disks, optical disks, magneto-optical disks, semiconductor memory, etc., are installed on the driver 610 as desired to facilitate the installation of computer programs read from the driver 610 into the storage portion 608 as desired.

The present disclosure also provides a non-transitory computer-readable storage medium, which may be included in the device/apparatus/system described in the above embodiments. It may also exist separately without being assembled into the device/apparatus/system. The computer-readable storage medium mentioned above carries one or more programs, and when one or more of the programs are executed, the methods of the embodiments of the present disclosure are implemented.

According to the embodiments of the present disclosure, the computer-readable storage medium may be non-volatile computer-readable storage medium, such as but not limited to: portable computer disks, hard disks, random access memory (RAM), read-only memory (ROM), erasable programmable read-only memory (EPROM or flash memory), portable compact disk read-only memory (CD-ROM), optical storage devices, magnetic storage devices or any suitable combination of the above. In the present disclosure, a computer-readable storage medium may be any tangible medium that contains or stores a program, which may be used by or in combination with an instruction execution system, a device, or a component. For example, according to the embodiments of the present disclosure, a computer-readable storage medium may include one or more memories other than ROM 602, and/or RAM 603, and/or ROM 602 and RAM 603 as described above.

The embodiment of the present disclosure also includes a computer program product, which includes a computer program containing a program code for executing the method shown in the flowchart. When the computer program product is running in a computer system, the program code is used to enable the computer system to implement a method of verifying process data of the product provided in the embodiment of the present disclosure.

When the computer program is executed by the processor 601, the above-mentioned functions defined in the system/device of the embodiments of the present disclosure are executed. According to the embodiments of the present disclosures, the systems, devices, modules, units, etc. described above may be implemented through computer program modules.

In an embodiment, the computer program may rely on tangible storage media such as optical storage devices and magnetic memory devices. In another embodiment, the computer program may also be transmitted, distributed in the form of signals on network media, and downloaded and installed through the communication portion 609, and/or installed from the detachable medium 611. The program code contained in this computer program may be transmitted using any suitable network medium, including but not limited to: wireless, wired, etc., or any suitable combination of the above.

In such embodiment, the computer program may be downloaded and installed from the network through the communication portion 609, and/or installed from the detachable medium 611. When the computer program is executed by the processor 601, the above-mentioned functions defined in the system of the embodiment of the present disclosure are executed. According to the embodiment of the present disclosure, the systems, devices, apparatuses, modules, units, etc. described above may be implemented through computer program modules.

According to the embodiments of the present disclosure, the program code for executing the computer program provided by the embodiments of the present disclosure may be written in any combination of one or more programming languages. Specifically, these computing programs may be implemented using advanced procedures and/or object-oriented programming languages, and/or assembly/machine languages. The programming languages include but are not limited to languages such as Java, C++, Python, “C” language or similar programming languages. The program code may be completely executed on user computing devices, partially executed on user devices, partially executed on remote computing devices, or completely executed on remote computing devices or servers. In the case of involving remote computing devices, remote computing devices may connect to user computing devices through any type of networks, including a local area network (LAN) or wide area network (WAN), or may connect to external computing devices (such as using an Internet service provider to connect through the Internet).

The flowcharts and block diagrams in the accompanying drawings illustrate possible architectures, functions, and operations of systems, methods, and computer program products according to various embodiments of the present disclosure. At this point, each box in the flowcharts or block diagrams may represent a module sub-circuit, program segment, or part of code that contains one or more executable instructions for implementing specified logical functions. It should also be noted that in some alternative implementations, the functions indicated in the boxes may also occur in a different order than those indicated in the accompanying drawings. For example, two consecutive boxes may actually be executed in parallel, and sometimes they may also be executed in the opposite order, depending on the function involved. It should also be noted that each box in the block diagrams or flowcharts, and combinations of boxes in the block diagrams or flowcharts, may be implemented using dedicated hardware based systems that perform specified functions or operations, or may be implemented using combinations of dedicated hardware and computer instructions.

Those of ordinary skilled in the art may understand that the features recorded in various embodiments and/or claims of the present disclosure may be combined and/or integrated in multiple ways, even if such combinations or integrations are not explicitly recorded in the present disclosure. Specifically, without departing from the spirit and teachings of the present disclosure, the features recorded in various embodiments and/or claims of the present disclosure may be combined and/or integrated in various ways. All these combinations and/or integrations fall within the scope of the present disclosure.

The embodiments of the present disclosure are described above. However, these embodiments are only for illustrative purposes and are not intended to limit the scope of the present disclosure. Although the various embodiments have been described separately above, this does not mean that the measures in the various embodiments may not be advantageously used in combination. The scope of the present disclosure is defined by the appended claims and their equivalents. Without departing from the scope of the present disclosure, those of ordinary skilled in the art may make various substitutions and modifications, all of which should fall within the scope of the present disclosure.

1. A method of verifying process data of a display panel, comprising:
generating, based on design data of a process of the display panel, simulation process data for performing the process;
performing, by using a process model, a simulation of performing the process based on the simulation process data; and
verifying, by using a measurement model, whether the simulation process data is applicable to actual production based on the simulation,
wherein the process model is constructed based on actual process data generated in an actual manufacturing process of the display panel, and the measurement model is constructed based on actual process data and actual measurement data which are generated in the actual manufacturing process of the display panel.

2. The method of claim 1, wherein the performing, by using a process model, a simulation of performing the process based on the simulation process data comprises:
determining, by using the process model, feature data of the display panel achievable by performing the process based on the simulation process data.

3. The method of claim 1, wherein the verifying, by using a measurement model, whether the simulation process data is applicable to actual production based on the simulation, comprises:
determining, among the actual process data, actual process data having a similarity higher than a preset similarity threshold with respect to the simulation process data, as similar process data by using the measurement model;
determining, among the actual measurement data, feature data of the display panel obtained by actually performing the process based on the similar process data, as actual feature data; and
determining that the simulation process data is applicable to actual production, in response to a difference between the actual feature data and the feature data output by the process model being less than a preset difference threshold.

4. The method of claim 1, further comprising, before verifying, by using the measurement model, whether the simulation process data is applicable to actual production based on the simulation;
calculating a process fluctuation by applying a feedback parameter algorithm to the actual process data by using a control model, and
applying the process fluctuation to the feature data output by the process model.

5. The method of claim 4, wherein the feedback parameter algorithm comprises one of a moving average algorithm, a weighted moving average algorithm, and or an exponential moving average algorithm.

6. The method of claim 5, wherein the moving average algorithm comprises calculating an average value of process parameters of a plurality of consecutive cycles according to an equation:
$$MA = \frac{{C}_{1} + {C}_{2} + ⋯ + {C}_{n}}{n}$$
where each of C₁, C₂, . . . Cₙ is a value of the process parameter of a respective cycle, and n is an integer greater than 1.

7. The method of claim 5, wherein the weighted moving average algorithm comprises one of a doomsday weighted algorithm, a linear weighted algorithm, a trapezoidal weighted algorithm, and or a square coefficient weighted algorithm.

8. The method of claim 7, wherein the doomsday weighted algorithm comprises calculating a weighted average value of process parameters of a plurality of consecutive cycles according to an equation:
$$WMA = \frac{{C}_{1} + {C}_{2} + ⋯ + {C}_{n} \times 2}{n + 1}$$
where each of C₁, C₂, . . . Cₙ is a value of the process parameter of a respective cycle, and n is an integer greater than 1;
wherein the linear weighted algorithm comprises calculating a weighted average value of process parameters of a plurality of consecutive cycles according to an equation:
$$WMA = \frac{{C}_{1} \times 1 + {C}_{2} \times 2 + ⋯ + {C}_{n} \times n}{1 + 2 + 3 + ⋯ + n}$$
where each of C₁, C₂, . . . Cₙ is a value of the process parameter of a respective cycle, and n is an integer greater than 1;
wherein the trapezoidal weighted algorithm comprises calculating a weighted average value of process parameters of a plurality of consecutive cycles according to an equation:
$$WMA = \frac{( {C}_{1} + {C}_{2} ) \times 1 + ( {C}_{2} + {C}_{3} ) \times 2 + ⋯ + ( {C}_{n - 1} + {C}_{n} ) \times ( n - 1 )}{2 \times 1 + 2 \times 2 + 2 \times 3 + ⋯ + 2 \times ( n - 1 )}$$
where each of C₁, C₂, . . . Cₙ is a value of the process parameter of a respective cycle, and n is an integer greater than 1;
wherein the square coefficient weighted algorithm comprises calculating a weighted average value of process parameters of a plurality of consecutive cycles according to an equation:
$$WMA = \frac{{C}_{1} \times {1}^{2} + {C}_{2} \times {2}^{2} + ⋯ + {C}_{n} \times {n}^{2}}{{1}^{1} + {2}^{2} + {3}^{2} + ⋯ + {n}^{2}}$$
where each of C₁, C₂, . . . Cₙ is a value of the process parameter of a respective cycle, and n is an integer greater than 1.

9-11. (canceled)

12. The method of claim 5, wherein the exponential moving average algorithm comprises calculating a weighted average value of process parameters of a plurality of consecutive cycles according to an equation:
$$EMA = \frac{{C}_{1} + ( 1 + α ) {C}_{2} + {( 1 + α )}^{2} {C}_{3} … + {( 1 + α )}^{n} {C}_{n}}{1 + ( 1 + α ) + {( 1 + α )}^{2} + ⋯ + {( 1 + α )}^{n}}$$
where each of C₁, C₂, . . . Cₙ is a value of the process parameter of a respective cycle, n is an integer greater than 1, and α is a weighted index.

13. The method of claim 1, wherein the process of the display panel comprises a backplane manufacturing process that includes a lithography process for forming a film layer, the design data comprises a design pattern of a mask, and the generating, based on design data of a process of the display panel, simulation process data for performing the process comprises at least one of:
simulating at least a part of the design pattern of the mask to obtain a test pattern;
generating an exposure process parameter based on a received exposure parameter setting information;
generating a resist process parameter based on a received resist parameter setting information; or
generating a development process parameter based on a received development parameter setting information.

14. (canceled)

15. The method of claim 13, wherein:
the exposure process parameter comprises at least one of a numerical aperture, a wavelength, a coherence factor, an illumination type, an exposure magnification, and a focus position; and
the resist process parameter comprises at least one of a type of photoresist, a thickness and development rate of photoresist, a substrate material, or a concentration distribution of photosensitive compound (PAC).

16. (canceled)

17. The method of claim 13, wherein the generating, based on design data of a process of the display panel, simulation process data for performing the process further comprises at least one of:
performing lens projection simulation on the test pattern based on the exposure process parameter to obtain aerial image data; or
generating graphic data of the film layer which has been developed, based on the development parameter.

18. The method of claim 17, further comprising:
presenting at least one of the aerial image data and the graphic data through a user interaction interface and receiving an input from a user, and
adjusting at least one of the exposure process parameter, the resist process parameter and the development process parameter based on the input from the user.

19. The method of claim 1, wherein the actual measurement data comprises data measured before starting the process and data measured after starting the process, and wherein the method further comprises:
updating the actual process data and the actual measurement data;
updating the process model and the measurement model based on updated actual process data and updated actual measurement data;
applying the simulation process data to the actual manufacturing process of the display panel in response to verifying that the simulation process data is applicable to actual production; and
forming the simulation process data which is verified to be applicable to actual production into a manufacturing process file.

20-22. (canceled)

23. An electronic device, comprising a memory and a processor, wherein the memory stores instructions executable by the processor, and the instructions, when executed by the processor, cause the processor to implement the method of claim 1.

24. A non-transitory computer readable storage medium storing computer instructions, wherein the computer instructions are configured to cause a computer to implement the method of claim 1.

25. (canceled)

26. A method of manufacturing a display panel, comprising a physical manufacturing process and a digital processing process, wherein:
in the physical manufacturing process, at least one process of the display panel is performed, so as to obtain actual process data and actual measurement data; and
in the digital processing process, the method of claim 1 is performed by using a process model and a measurement model which are generated based on the actual process data and the actual measurement data, so as to verify whether simulation process data is applicable to actual production.

27. The method of claim 26, wherein performing at least one process of the display panel in the physical manufacturing process comprises:
sequentially performing a pre-measurement operation, a preparation operation, a loading process data operation, a processing operation, and a post-measurement operation,
wherein the actual process data is loaded in the loading process data operation, and the actual measurement data is generated in at least one of the pre-measurement operation, the processing operation and the post-measurement operation.

28. The method of claim 26, further comprising:
applying the simulation process data as actual process data to the loading process data operation in the physical manufacturing process, in response to verifying that the simulation process data is applicable to actual production.

29. The method of claim 26, further comprising:
re-performing the physical manufacturing process to generate new actual process data and new actual measurement data; and
updating the process model and the measurement model based on the new actual process data and the new actual measurement data.
